(19) United States
(12) Patent Application Publication
(10) Pub. No.: US 2026/0293291 A1
(43) Pub. Date: Sep. 24, 2026

(54) SEMICONDUCTOR DIE HAVING A CURRENT-DRIVEN TRANSISTOR, A CHARGE INJECTION DIODE DEVICE AND A PULLDOWN DEVICE

(71) Applicant: Infineon Technologies Austria AG, Villach (AT)

(72) Inventors: Manuel Vorwerk, Villach (AT); Bhargav Pandya, Gilbert, AZ (US); Alexander Young, Scottsdale, AZ (US)

(21) Appl. No.: 19/086,772

(22) Filed: Mar. 21, 2025

(51) Int. Cl. H10D 84/80; H10D 30/47

(52) U.S. Cl. CPC H10D 84/811; H10D 30/475

(57) ABSTRACT

A semiconductor die includes: a heteroepitaxial structure including a first semiconductor layer, a second semiconductor layer on the first semiconductor layer, and a two-dimensional charge carrier gas at or near an interface between the first and second semiconductor layers; in a first region of the semiconductor die, a first current-driven HEMT having a p-type gate region recessed into the second semiconductor layer such that the two-dimensional charge carrier gas is interrupted underneath the p-type gate region; in a second region of the semiconductor die, a diode device configured to inject charges into the p-type gate region in forward bias; and in a third region of the semiconductor die, a pulldown device electrically connected between the p-type gate region and a source of the first current-driven HEMT. The two-dimensional charge carrier gas extends uninterrupted from the first region into the second region and from the second region into the third region.

### BACKGROUND

One type of normally-off GaN-based transistor, referred to herein as a gate injection transistor (GIT) high-electron-mobility transistor (HEMT), utilizes hole-injection from a p-GaN region to an AlGaN/GaN heterojunction, which simultaneously increases electron density in the channel, to yield a dramatic increase in drain current due to conductivity modulation. The gate of GIT HEMTs effectively behave like a diode (i.e., current driven) as opposed to power MOSFETs which are voltage driven. GIT HEMTs offer robust gate performance with a self-clamping mechanism. However, GIT HEMTs require a small current to be injected into the gate to enable conductivity modulation, which leads to drawbacks under certain conditions. For example, a larger gate current is needed when increasing gate width and switching frequency. Increasing the voltage slew rate (i.e., increasing ΔV/Δt) may require a package concept without the gate exposed, making gate current control more difficult. Increasing saturation current (ID_{SAT}) also requires a relatively large gate current.

Therefore, there is a need for improved gate current drive technique for GIT HEMTs.

### SUMMARY

According to an embodiment of a semiconductor die, the semiconductor die comprises: a heteroepitaxial structure comprising a first semiconductor layer, a second semiconductor layer on the first semiconductor layer, and a two-dimensional charge carrier gas at or near an interface between the first semiconductor layer and the second semiconductor layer; in a first region of the semiconductor die, a first current-driven HEMT (high electron mobility transistor) having a p-type gate region recessed into the second semiconductor layer such that the two-dimensional charge carrier gas is interrupted underneath the p-type gate region; in a second region of the semiconductor die, a diode device configured to inject charges into the p-type gate region in forward bias; and in a third region of the semiconductor die, a pulldown device electrically connected between the p-type gate region and a source of the first current-driven HEMT, wherein the two-dimensional charge carrier gas extends uninterrupted from the first region into the second region and from the second region into the third region.

According to another embodiment of a semiconductor die, the semiconductor die comprises: a first gate terminal; a source terminal; a drain terminal; a heteroepitaxial structure comprising a first semiconductor layer, a second semiconductor layer on the first semiconductor layer, and a two-dimensional charge carrier gas at or near an interface between the first semiconductor layer and the second semiconductor layer; in a first region of the semiconductor die, a first current-driven HEMT (high electron mobility transistor) having a p-type gate region recessed into the second semiconductor layer such that the two-dimensional charge carrier gas is interrupted underneath the p-type gate region; in a second region of the semiconductor die, a diode device electrically connecting the first gate terminal to the p-type gate region; and in a third region of the semiconductor die, a pulldown device electrically connected between the p-type gate region and a source of the first current-driven HEMT, wherein the two-dimensional charge carrier gas extends uninterrupted from the first region into the second region and from the second region into the third region.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1 through 5 illustrate respective schematic diagrams of a semiconductor die that includes a current-driven HEMT and a monolithically integrated diode device that drives the gate of the current-driven HEMT, according to various embodiments.

FIG. 6 illustrates a cross-sectional view of part of the semiconductor die, according to another embodiment.

FIGS. 7 and 8 illustrate respective cross-sectional views of the diode device monolithically integrated in the semiconductor die, according to additional embodiments.

FIGS. 9 through 11 illustrate respective cross-sectional views of a pulldown device monolithically integrated in the semiconductor die, according to various embodiments.

### DETAILED DESCRIPTION

Embodiments described herein provide a monolithic integration of a diode device in the same semiconductor die as a current-driven HEMT (high electron mobility transistor) having a recessed p-type gate region that interrupts the two-dimensional charge carrier gas underneath the p-type gate region, to drive the gate of the current-driven HEMT (high electron mobility transistor). The diode device enables a reduction of threshold voltage which leads to a smaller gate current required for driving the current-driven HEMT, without any drawback in saturation current, thus enabling new applications for devices based on the GIT HEMT concept. The current-driven HEMT could also be driven without any reduction in gate current, yielding an increase in saturation current, which is beneficial for applications that require an increase in saturation current such as AC line drop condition in a PFC (power factor correction) stage. A pulldown device for the current-driven HEMT may also be monolithically integrated in the same semiconductor die as the current-driven HEMT and the diode device.

Described next with reference to the figures are embodiments of a semiconductor die that includes a current-driven HEMT and a diode device that drives the gate of the current-driven HEMT.

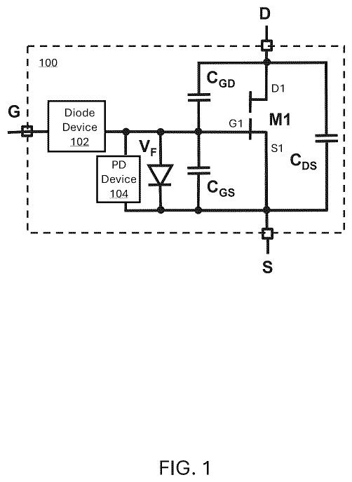

FIG. 1 illustrates a schematic diagram of an embodiment of a semiconductor die 100 that includes a current-driven HEMT M1 and a diode device 102 that drives the gate G1 of the current-driven HEMT M1. The diode device 102 may be a pn diode, a Schottky diode, a merged pn-Schottky (MPS) structure, a gated diode with the gate and source shorted together, or any other type of device having a diodic behavior (i.e., of, pertaining to, or functioning as a diode). The semiconductor die 100 may also include a pulldown device 104 electrically connected between the gate G1 and the source S1 of the current-driven HEMT M1.

The gate G1 of the current-driven HEMT M1 includes a recessed p-type region (not shown in the schematic view of FIG. 1) that interrupts a two-dimensional charge carrier gas (also not shown in the schematic view of FIG. 1) underneath the p-type gate region, where the two-dimensional charge carrier gas forms the conductive channel of the current-driven HEMT M1. The p-type region of the gate G1 of the current-driven HEMT effectively behaves like a diode (i.e., current driven). Accordingly, the current-driven HEMT M1 is a normally-off GIT device.

In the case of an n-channel device, the two-dimensional charge carrier gas is a two-dimensional electron gas. In the case of a p-channel device, the two-dimensional charge carrier gas is a two-dimensional hole gas. In either case, the pulldown device 104 electrically connected between the gate G1 and the source S1 of the current-driven HEMT M1 is any type of device capable of pulling down the gate G1, ensuring that the current-driven HEMT M1 remains off when the pulldown device 104 is active/on.

In forward bias, the diode device 102 injects charges into the p-type region of the gate G1 of the current-driven HEMT M1. When the p-type gate region of the current-driven HEMT M1 turns on/is forward biased, charges (holes) stored in the p-type gate region are released and become recombined into the gate G1 to contribute to a gate current I_{GS} which turns on the current-driven HEMT M1. The threshold voltage of the current-driven HEMT M1 is a key parameter for the saturation current (ID_{SAT}), where lower threshold voltage yields stronger on current (I_{DS}) between the source S1 and drain D1 of the current-driven HEMT M1. Conventionally, threshold voltage adjustment is achieved by tuning the thickness of an AlGaN barrier via a regrowth concept.

The diode device 102 described herein enables threshold voltage reduction, which yields a reduction in the gate current I_{GS} required to drive the current-driven HEMT M1 without any significant impact on the forward voltage of the gate diode that is part of the gate G1 of the current-driven HEMT M1. Simulations show that adjusting the gate overdrive of the current-driven HEMT M1 via the diode device 102 to keep a constant drain current I_{DS} leads to 10× reduction in gate current I_{GS}. The current-driven HEMT M1 instead may be driven without any reduction in gate current, yielding an increase in saturation current.

The diode part of the gate G1 of the current-driven HEMT M1 is represented by the diode labeled ‘V_{F}’ in FIG. 1. The gate-to-source capacitance of the current-driven HEMT M1 is represented by the capacitor labeled ‘C_{GS}’ in FIG. 1. The gate-to-drain capacitance of the current-driven HEMT M1 is represented by the capacitor labeled ‘C_{GD}’ in FIG. 1. The drain-to-source capacitance of the current-driven HEMT M1 is represented by the capacitor labeled ‘C_{DS}’ in FIG. 1.

The semiconductor die 100 also includes a gate terminal ‘G’ for controlling the gate G1 of the current-driven HEMT M1, a source terminal ‘S’ electrically connected to the source S1 of the current-driven HEMT M1, and a drain terminal ‘D’ electrically connected to the drain D1 of the current-driven HEMT M1. The terminals G, S, D enable points of external electrical contact to the semiconductor die 100, for providing signal, power and/or ground connections to the semiconductor die 100. That is, the terminals G, S, D that are part of the semiconductor die 100 can be electrically contacted by a component outside the die 100, and bring the corresponding signal/power/ground connection to the corresponding node(s) within the die 100. The terminals G, S, D of the semiconductor die 100 may be implemented as pins, leads, busbars, tabs, pads, etc.

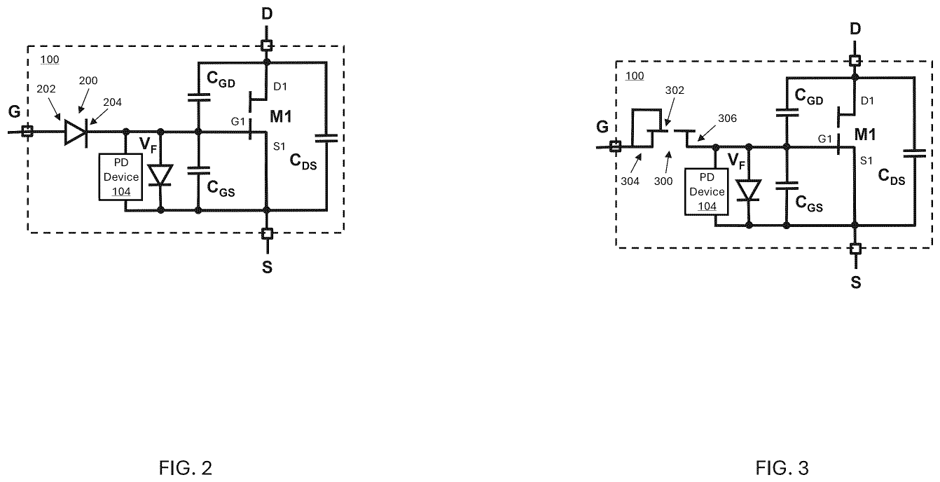

FIG. 2 illustrates a schematic diagram of the semiconductor die 100, according to another embodiment. In FIG. 2, the diode device 102 is implemented as a diode 200. The anode 202 of the diode 200 is electrically connected to the gate terminal G of the semiconductor die 100. The cathode 204 of the diode is electrically connected to the gate G1 of the current-driven HEMT M1.

FIG. 3 illustrates a schematic diagram of the semiconductor die 100, according to another embodiment. In FIG. 3, the diode device 102 is implemented as a gated diode 300. The gated diode is a transistor structure that has a gate 302 and a source 304 shorted together. The gate 302 and the source 304 of the gated diode 300 are electrically connected to the gate terminal G of the semiconductor die 100. The drain 306 of the gated diode 300 is electrically connected to the gate G1 of the current-driven HEMT M1.

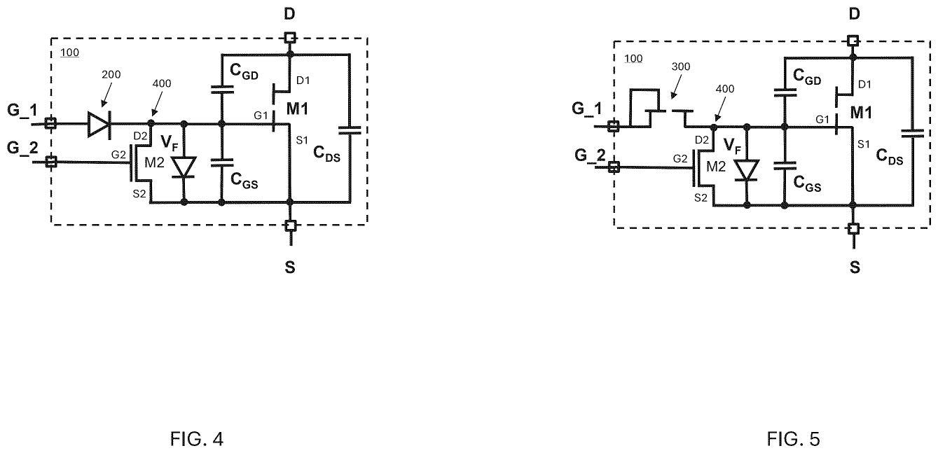

FIG. 4 illustrates a schematic diagram of the semiconductor die 100, according to another embodiment. The embodiment shown in FIG. 4 is similar to the embodiment shown in FIG. 2. In FIG. 4, the pulldown device 104 is implemented as a second current-driven HEMT M2 having a gate G2 with a recessed p-type gate region (not shown in the schematic view of FIG. 4) that interrupts the two-dimensional charge carrier gas underneath the p-type gate region of the second (pulldown) current-driven HEMT M2. The source S2 of the pulldown current-driven HEMT M2 is electrically connected to the source of the main (power) current-driven HEMT M1. The drain D2 of the pulldown current-driven HEMT M2 is electrically connected to the gate G1 of the main current-driven HEMT M1, e.g., at an intermediary node 400 between the diode device 102 and the gate G1 of the main current-driven HEMT M1.

Also in FIG. 4, the gates G1, G2 of the current-driven HEMTs M1, M2 are electrically connected to different gate terminals G_1, G_2 of the semiconductor die 100 that are electrically isolated from one another. According to this embodiment, the main current-driven HEMT M1 is controlled via a first gate terminal G_1 of the semiconductor die 100 and the pulldown current-driven HEMT M2 is controlled via a second gate terminal G_2 of the semiconductor die 100 that is electrically isolated from the first gate terminal G_1 of the die 100.

FIG. 5 illustrates a schematic diagram of the semiconductor die 100, according to another embodiment. The embodiment shown in FIG. 5 is similar to the embodiment shown in FIG. 4. In FIG. 5, the gated diode 300 shown in FIG. 3 is used as the pulldown device 102 instead of the diode 200 shown in FIG. 2.

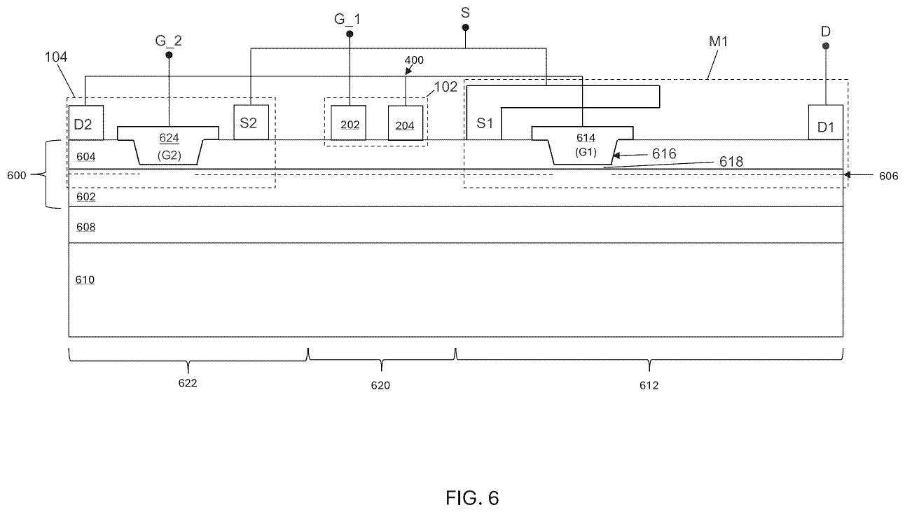

FIG. 6 illustrates a cross-sectional view of part of the semiconductor die 100, according to another embodiment. In FIG. 6, the semiconductor die 100 includes a heteroepitaxial structure 600 that includes a first semiconductor layer 602 and a second semiconductor layer 604 on the first semiconductor layer 602. The first and second semiconductor layers 602, 604 have different bandgap energies, and a two-dimensional charge carrier gas 606 is present at or near the interface between the first and second semiconductor layers 602, 604. As previously described, the two-dimensional charge carrier gas 606 is a two-dimensional electron gas in the case of an n-channel device and a two-dimensional hole gas in the case of a p-channel device.

In one embodiment, the first semiconductor layer 602 is a GaN layer and the second semiconductor layer 604 is an AlGaN layer. However, other heteroepitaxial material systems may be used. For example, the heteroepitaxial structure 600 may include InP, InN, InAlN, InGaN, GaN with an AlN spacer, GaAs, AlGaAs, etc. In each case, the junction between the first and second semiconductor layers 602, 604 of materials with different bandgaps gives rise to the two-dimensional charge carrier gas 606, which forms the channel of the main current-driven HEMT M1 (and of the pulldown current-driven HEMT M2) instead of a doped region. One or more transition layers 608 may be formed below the first semiconductor layer 602, e.g., such as one or more nucleation layers on a substrate 610 such as silicon, silicon carbide, sapphire, etc.

The main current-driven HEMT M1 is formed in a first region 612 of the semiconductor die 100. The main current-driven HEMT M1 includes a p-type gate region 614 recessed into the second semiconductor layer 604 such that the two-dimensional charge carrier gas 606 is interrupted underneath the p-type gate region 614, as indicated in FIG. 6 by the rightmost break in the dashed line that represents the two-dimensional charge carrier gas 606. The recessed p-type gate region 614 of the main current-driven HEMT M1 may have a T-like shape with the thinner part of the p-type gate region 614 being formed on the upper surface of the second semiconductor layer 604 (e.g., AlGaN) and the thicker part of the p-type gate region 614 being disposed in a recess 616 formed in the upper surface of the second semiconductor layer 604. The thinner part 618 of the second semiconductor layer 604 remaining at the bottom of the recess 616 separates the p-type gate region 614 (e.g., p-GaN, p-AlGaN, etc.) of the main current-driven HEMT M1 from the underlying first semiconductor layer 602.

The diode device 102 is formed in a second region 620 of the semiconductor die 100. The diode device 102 injects charges into the p-type gate region 614 of the main current-driven HEMT M1 in forward bias. The diode device 102 is implemented in FIG. 6 as the diode 200 shown in FIG. 2 and FIG. 4, with the anode 202 of the diode electrically connected to the first gate terminal G_1 of the semiconductor die 100 that controls the main current-driven HEMT M1, and the cathode 204 of the diode electrically connected to the p-type gate region 614 of the main current-driven HEMT M1. However, the diode device 102 may be any type of device having a diodic behavior. For example, the diode device 102 may be implemented as the gated diode 300 shown in FIG. 3 and FIG. 5, by forming a HEMT device in the second region 620 of the die 100 but with the source and gate of the HEMT device shorted together and electrically connected to the first gate terminal G_1 of the semiconductor die 100 that controls the main current-driven HEMT M1.

The pulldown device 104 is formed in a third region 622 of the semiconductor die 100. The pulldown device 104 is implemented in FIG. 6 as the current-driven HEMT M2 in FIG. 4 and FIG. 5, and is electrically connected between the p-type gate region 614 and the source S1 of the main current-driven HEMT M1. The pulldown current-driven HEMT M2 has a recessed p-type gate region 624 that interrupts the two-dimensional charge carrier gas 606 underneath the p-type gate region 624 of the pulldown current-driven HEMT M2, as indicated in FIG. 6 by the leftmost break in the dashed line that represents the two-dimensional charge carrier gas 606. The p-type gate region 624 of the pulldown current-driven HEMT M2 may be recessed in the same or similar manner as the p-type gate region 614 of the main current-driven HEMT M1, as described above. The source S2 of the pulldown current-driven HEMT M2 and the source S1 of the main current-driven HEMT M1 are electrically connected to one another and to the source terminal S of the semiconductor die 100. The drain D2 of the pulldown current-driven HEMT M2 is electrically connected to the p-type gate region 614 of the main current-driven HEMT M1. The respective sources S1, S2 and drains D1, D2 of the current-driven HEMTs M1, M2 may be implemented as doped semiconductor regions and/or metallic contacts.

No channel/two-dimensional charge carrier gas isolation is required between the diode device 102 and the main current-driven HEMT M1. That is, the diode device 102 and the main current-driven HEMT M1 may be formed side-by-side in a truly monolithic solution without isolation, and sharing a common channel/two-dimensional charge carrier gas 606, e.g., as shown in FIG. 6. Such a layout avoids unnecessary processing. Also, if isolation is used, implementation of the pulldown device 104 becomes more challenging. The embodiment illustrated in FIG. 6 does not use isolation to separate the channel/two-dimensional charge carrier gas 606 between the main current-driven HEMT M1 and the diode device 102. Accordingly, the two-dimensional charge carrier gas 606 extends uninterrupted from the first region 612 of the semiconductor die 100 into the second region 620 of the die 100, and from the second region 620 into the third region 622 of the die 100 in FIG. 6. The only interruption of the two-dimensional charge carrier gas 606 in FIG. 6 occurs underneath the p-type gate region 624 of the pulldown current-driven HEMT M2 and underneath the p-type gate region 614 of the main current-driven HEMT M1.

When the main current-driven HEMT M1 turns on in the forward direction, it may be preferable to have a lower threshold voltage so as to have a higher saturation current, but this can increase the risk of spurious turn-on due to an inherent Miller clamp effect. The pulldown device 104 mitigates such spurious turn-on. Pulling down the p-type gate region 614 of the main current-driven HEMT M1 via the pulldown device 104 ensures smaller gate driver losses and, for the same gate current I_{GS}, yields a higher ID_{SAT} while ensuring the main current-driven HEMT M1 safely turns off.

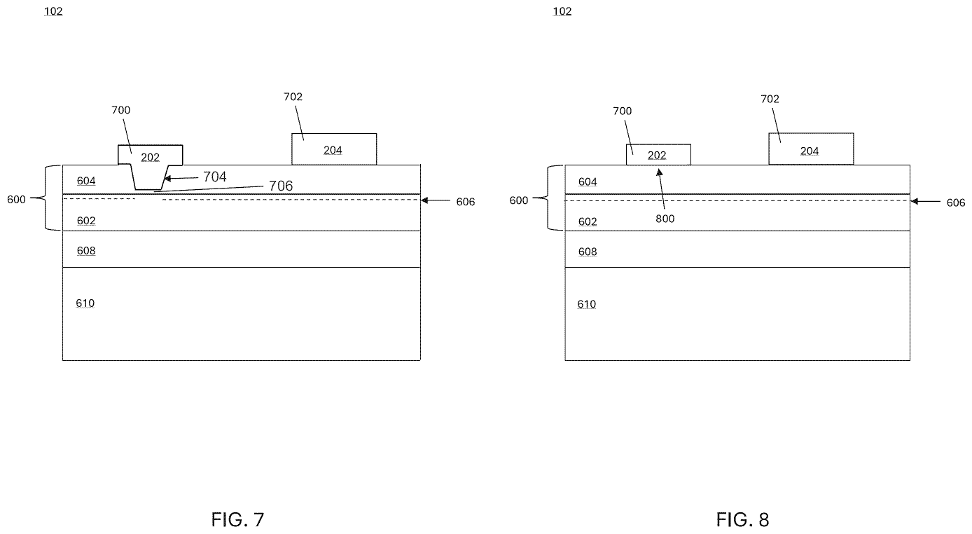

FIG. 7 illustrates a cross-sectional view of the diode device 102 monolithically integrated in the semiconductor die 100, according to an embodiment. In FIG. 7, the diode device 102 includes an anode 202 electrically connected to the first gate terminal G_1 of the semiconductor die 100 that controls the main current-driven HEMT M1, and a cathode 204 electrically connected to the p-type gate region 614 of the main current-driven HEMT M1. The anode 202 of the diode device 102 may be implemented by, e.g., a p-type GaN or AlGaN region 700 and the cathode 204 of the diode device 102 may be implemented by, e.g., an n-type GaN or AlGaN region 702.

In FIG. 7, the p-type anode region 700 of the diode device 102 is recessed into the second semiconductor layer 604 of the heteroepitaxial structure 600 such that the two-dimensional charge carrier gas 606 is interrupted underneath the p-type anode region 700, as indicated in FIG. 7 by the break in the dashed line that represents the two-dimensional charge carrier gas 606. The p-type anode region 700 may have a T-like shape with the thinner part of the p-type anode region 700 being formed on the upper surface of the second semiconductor layer 604 (e.g., AlGaN) and the thicker part of the p-type anode region 700 being disposed in a recess 704 formed in the upper surface of the second semiconductor layer 604. The thinner part 706 of the second semiconductor layer 604 remaining at the bottom of the recess 704 separates the p-type anode region 700 (e.g., p-GaN, p-AlGaN, etc.) from the underlying first semiconductor layer 602. The n-type cathode region 702 of the diode device 102 is not recessed into the second semiconductor layer 604 in FIG. 7.

FIG. 8 illustrates a cross-sectional view of the diode device 102 monolithically integrated in the semiconductor die 100, according to another embodiment. The embodiment shown in FIG. 8 is similar to the embodiment shown in FIG. 7. Different, however, the p-type anode region 700 of the diode device 102 is formed on an un-recessed part 800 of the second semiconductor layer 604 of the heteroepitaxial structure 600. According to this embodiment, the two-dimensional charge carrier gas 606 is not interrupted underneath the p-type anode region 700 of the diode device 102. That is, no recess is formed in the upper surface of the second semiconductor layer 604 and both the p-type anode region 700 and the n-type cathode region 702 of the diode device 102 are formed entirely on the upper surface of the second semiconductor layer 604.

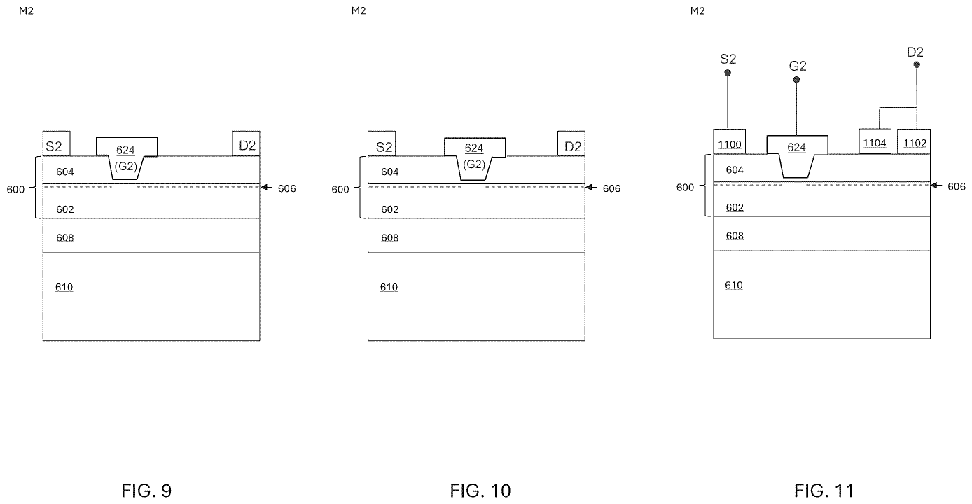

FIG. 9 illustrates a cross-sectional view of the pulldown device 104 monolithically integrated in the semiconductor die 100, according to an embodiment. In FIG. 9, the p-type gate region 624 of the pulldown current-driven HEMT M2 is positioned closer to the source S2 of the pulldown current-driven HEMT M2 than to the drain D2 of the pulldown current-driven HEMT M2.

FIG. 10 illustrates a cross-sectional view of the pulldown device 104 monolithically integrated in the semiconductor die 100, according to another embodiment. In FIG. 10, the p-type gate region 624 of the pulldown current-driven HEMT M2 is spaced equidistant from the source S2 and the drain D2 of the pulldown current-driven HEMT M2.

FIG. 11 illustrates a cross-sectional view of the pulldown device 104 monolithically integrated in the semiconductor die 100, according to another embodiment. In FIG. 11, the pulldown current-driven HEMT M2 includes a metallic source contact 1100, a metallic drain contact 1102, and
a p-type region 1104 (e.g., p-GaN, p-AlGaN, etc.) on the second semiconductor layer 604 of the heteroepitaxial structure 600 between the metallic drain contact 1102 and the p-type gate region 624 of the pulldown current-driven HEMT M2.

Although the present disclosure is not so limited, the following numbered examples demonstrate one or more aspects of the disclosure.

Example 1. A semiconductor die, comprising: a heteroepitaxial structure comprising a first semiconductor layer, a second semiconductor layer on the first semiconductor layer, and a two-dimensional charge carrier gas at or near an interface between the first semiconductor layer and the second semiconductor layer; in a first region of the semiconductor die, a first current-driven HEMT (high electron mobility transistor) having a p-type gate region recessed into the second semiconductor layer such that the two-dimensional charge carrier gas is interrupted underneath the p-type gate region; in a second region of the semiconductor die, a diode device configured to inject charges into the p-type gate region in forward bias; and in a third region of the semiconductor die, a pulldown device electrically connected between the p-type gate region and a source of the first current-driven HEMT, wherein the two-dimensional charge carrier gas extends uninterrupted from the first region into the second region and from the second region into the third region.

Example 2. The semiconductor die of example 1, wherein the pulldown device comprises a second current-driven HEMT having a p-type gate region recessed into the second semiconductor layer such that the two-dimensional charge carrier gas is interrupted underneath the p-type gate region of the second current-driven HEMT.

Example 3. The semiconductor die of example 2, wherein the p-type gate region of the second current-driven HEMT is positioned closer to a source of the second current-driven HEMT than to a drain of the second current-driven HEMT.

Example 4. The semiconductor die of example 2, wherein the p-type gate region of the second current-driven HEMT is spaced equidistant from a source and a drain of the second current-driven HEMT.

Example 5. The semiconductor die of any of examples 2 through 4, wherein the second current-driven HEMT further comprises: a metallic source contact; a metallic drain contact; and a p-type region on the second semiconductor layer between the metallic drain contact and the p-type gate region of the second current-driven HEMT.

Example 6. The semiconductor die of any of examples 2 through 5, wherein the first current-driven HEMT is controlled via a first gate terminal of the semiconductor die and the second current-driven HEMT is controlled via a second gate terminal of the semiconductor die electrically isolated from the first gate terminal.

Example 7. The semiconductor die of any of examples 1 through 6, wherein the diode device comprises an anode electrically connected to a gate terminal of the semiconductor die and a cathode electrically connected to the p-type gate region of the first current-driven HEMT.

Example 8. The semiconductor die of example 7, wherein the anode comprises a p-type region recessed into the second semiconductor layer.

Example 9. The semiconductor die of example 7, wherein the anode comprises a p-type region formed on an un-recessed part of the second semiconductor layer.

Example 10. The semiconductor die of any of examples 1 through 6, wherein the diode device is a gated diode having a gate and a source electrically connected to a gate terminal of the semiconductor die and a drain electrically connected to the p-type gate region of the first current-driven HEMT.

Example 11. A semiconductor die, comprising: a first gate terminal; a source terminal; a drain terminal; a heteroepitaxial structure comprising a first semiconductor layer, a second semiconductor layer on the first semiconductor layer, and a two-dimensional charge carrier gas at or near an interface between the first semiconductor layer and the second semiconductor layer; in a first region of the semiconductor die, a first current-driven HEMT (high electron mobility transistor) having a p-type gate region recessed into the second semiconductor layer such that the two-dimensional charge carrier gas is interrupted underneath the p-type gate region; in a second region of the semiconductor die, a diode device electrically connecting the first gate terminal to the p-type gate region; and in a third region of the semiconductor die, a pulldown device electrically connected between the p-type gate region and a source of the first current-driven HEMT, wherein the two-dimensional charge carrier gas extends uninterrupted from the first region into the second region and from the second region into the third region.

Example 12. The semiconductor die of example 11, wherein the pulldown device comprises a second current-driven HEMT having a p-type gate region recessed into the second semiconductor layer such that the two-dimensional charge carrier gas is interrupted underneath the p-type gate region of the second current-driven HEMT.

Example 13. The semiconductor die of example 12, wherein the p-type gate region of the second current-driven HEMT is positioned closer to a source of the second current-driven HEMT than to a drain of the second current-driven HEMT.

Example 14. The semiconductor die of example 12, wherein the p-type gate region of the second current-driven HEMT is spaced equidistant from a source and a drain of the second current-driven HEMT.

Example 15. The semiconductor die of any of examples 12 through 14, wherein the second current-driven HEMT further comprises: a metallic source contact; a metallic drain contact; and a p-type region on the second semiconductor layer between the metallic drain contact and the p-type gate region of the second current-driven HEMT.

Example 16. The semiconductor die of any of examples 12 through 15, further comprising: a second gate terminal electrically isolated from the first gate terminal, wherein the first current-driven HEMT is controlled via the first gate terminal and the second current-driven HEMT is controlled via the second gate terminal.

Example 17. The semiconductor die of any of examples 11 through 16, wherein the diode device comprises an anode electrically connected to the first gate terminal and a cathode electrically connected to the p-type gate region of the first current-driven HEMT.

Example 18. The semiconductor die of example 17, wherein the anode comprises a p-type region recessed into the second semiconductor layer.

Example 19. The semiconductor die of example 17, wherein the anode comprises a p-type region formed on an un-recessed part of the second semiconductor layer.

Example 20. The semiconductor die of any of examples 11 through 16, wherein the diode device is a gated diode having a gate and a source electrically connected to the first gate terminal and a drain electrically connected to the p-type gate region of the first current-driven HEMT.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor die, comprising:
a heteroepitaxial structure comprising a first semiconductor layer, a second semiconductor layer on the first semiconductor layer, and a two-dimensional charge carrier gas at or near an interface between the first semiconductor layer and the second semiconductor layer;
in a first region of the semiconductor die, a first current-driven HEMT (high electron mobility transistor) having a p-type gate region recessed into the second semiconductor layer such that the two-dimensional charge carrier gas is interrupted underneath the p-type gate region;
in a second region of the semiconductor die, a diode device configured to inject charges into the p-type gate region in forward bias; and
in a third region of the semiconductor die, a pulldown device electrically connected between the p-type gate region and a source of the first current-driven HEMT,
wherein the two-dimensional charge carrier gas extends uninterrupted from the first region into the second region and from the second region into the third region.

2. The semiconductor die of claim 1, wherein the pulldown device comprises a second current-driven HEMT having a p-type gate region recessed into the second semiconductor layer such that the two-dimensional charge carrier gas is interrupted underneath the p-type gate region of the second current-driven HEMT.

3. The semiconductor die of claim 2, wherein the p-type gate region of the second current-driven HEMT is positioned closer to a source of the second current-driven HEMT than to a drain of the second current-driven HEMT.

4. The semiconductor die of claim 2, wherein the p-type gate region of the second current-driven HEMT is spaced equidistant from a source and a drain of the second current-driven HEMT.

5. The semiconductor die of claim 2, wherein the second current-driven HEMT further comprises:
a metallic source contact;
a metallic drain contact; and
a p-type region on the second semiconductor layer between the metallic drain contact and the p-type gate region of the second current-driven HEMT.

6. The semiconductor die of claim 2, wherein the first current-driven HEMT is controlled via a first gate terminal of the semiconductor die and the second current-driven HEMT is controlled via a second gate terminal of the semiconductor die electrically isolated from the first gate terminal.

7. The semiconductor die of claim 1, wherein the diode device comprises an anode electrically connected to a gate terminal of the semiconductor die and a cathode electrically connected to the p-type gate region of the first current-driven HEMT.

8. The semiconductor die of claim 7, wherein the anode comprises a p-type region recessed into the second semiconductor layer.

9. The semiconductor die of claim 7, wherein the anode comprises a p-type region formed on an un-recessed part of the second semiconductor layer.

10. The semiconductor die of claim 1, wherein the diode device is a gated diode having a gate and a source electrically connected to a gate terminal of the semiconductor die and a drain electrically connected to the p-type gate region of the first current-driven HEMT.

11. A semiconductor die, comprising:
a first gate terminal;
a source terminal;
a drain terminal;
a heteroepitaxial structure comprising a first semiconductor layer, a second semiconductor layer on the first semiconductor layer, and a two-dimensional charge carrier gas at or near an interface between the first semiconductor layer and the second semiconductor layer;
in a first region of the semiconductor die, a first current-driven HEMT (high electron mobility transistor) having a p-type gate region recessed into the second semiconductor layer such that the two-dimensional charge carrier gas is interrupted underneath the p-type gate region;
in a second region of the semiconductor die, a diode device electrically connecting the first gate terminal to the p-type gate region; and
in a third region of the semiconductor die, a pulldown device electrically connected between the p-type gate region and a source of the first current-driven HEMT,
wherein the two-dimensional charge carrier gas extends uninterrupted from the first region into the second region and from the second region into the third region.

12. The semiconductor die of claim 11, wherein the pulldown device comprises a second current-driven HEMT having a p-type gate region recessed into the second semiconductor layer such that the two-dimensional charge carrier gas is interrupted underneath the p-type gate region of the second current-driven HEMT.

13. The semiconductor die of claim 12, wherein the p-type gate region of the second current-driven HEMT is positioned closer to a source of the second current-driven HEMT than to a drain of the second current-driven HEMT.

14. The semiconductor die of claim 12, wherein the p-type gate region of the second current-driven HEMT is spaced equidistant from a source and a drain of the second current-driven HEMT.

15. The semiconductor die of claim 12, wherein the second current-driven HEMT further comprises:
a metallic source contact;
a metallic drain contact; and
a p-type region on the second semiconductor layer between the metallic drain contact and the p-type gate region of the second current-driven HEMT.

16. The semiconductor die of claim 12, further comprising:
a second gate terminal electrically isolated from the first gate terminal,
wherein the first current-driven HEMT is controlled via the first gate terminal and the second current-driven HEMT is controlled via the second gate terminal.

17. The semiconductor die of claim 11, wherein the diode device comprises an anode electrically connected to the first gate terminal and a cathode electrically connected to the p-type gate region of the first current-driven HEMT.

18. The semiconductor die of claim 17, wherein the anode comprises a p-type region recessed into the second semiconductor layer.

19. The semiconductor die of claim 17, wherein the anode comprises a p-type region formed on an un-recessed part of the second semiconductor layer.

20. The semiconductor die of claim 11, wherein the diode device is a gated diode having a gate and a source electrically connected to the first gate terminal and a drain electrically connected to the p-type gate region of the first current-driven HEMT.
